(19) United States
(12) Patent Application Publication
(10) Pub. No.: US 2025/0293001 A1
(43) Pub. Date: Sep. 18, 2025

(54) CHANNEL STRUCTURE, SEMICONDUCTOR MANUFACTURING DEVICE, AND METHOD FOR MANUFACTURING CHANNEL STRUCTURE

(71) Applicant: KYOCERA Corporation, Kyoto-shi, Kyoto (JP)

(72) Inventors: Kazuhiko FUJIO, Satsumasendai-shi, Kagoshima (JP); Yasunori KAWANABE, Kirishima-shi, Kagoshima (JP)

(21) Appl. No.: 18/868,000

(22) PCT Filed: May 24, 2023
(86) PCT No.: PCT/JP2023/019405

§ 371 Date: Nov. 21, 2024

(30) Foreign Application Priority Data
May 31, 2022 (JP) 2022-088974
May 31, 2022 (JP) 2022-088975

(51) Int. Cl. H01J 37/32; H01J 9/30

(52) U.S. Cl. CPC H01J 37/3244; H01J 9/30; H01J 37/32477; H01J 2237/022

(57) ABSTRACT

A channel structure includes a base and a channel. The base has a first opening on a first surface. The channel is located inside the base and is connected to the first opening. The base has a plurality of grooves on the first surface. The plurality of grooves include a plurality of first grooves and a plurality of second grooves. The plurality of first grooves extend along a first direction. The plurality of second grooves extend along a second direction intersecting the first direction.

### TECHNICAL FIELD

An embodiment of the disclosure relates to a channel structure, a semiconductor manufacturing device, and a method for manufacturing a channel structure.

### BACKGROUND OF INVENTION

In a semiconductor manufacturing process, a plasma processing device accommodates a wafer, which is an object to be processed, in a chamber and processes the wafer with plasma in a vacuum atmosphere. In the related art, there is disclosed a technique for reducing contamination of an object to be processed which is caused when a process by-product such as dust deposited on an inner wall of a chamber or the like is peeled off and falls on the object to be processed.

### CITATION LIST

### Patent Literature

Patent Document 1: JP 2007-63595 A

### SUMMARY

A channel structure of the present disclosure includes a base and a channel. The base has a first opening on a first surface. The channel is located inside the base and is connected to the first opening. The base has a plurality of grooves on the first surface. The plurality of grooves include a plurality of first grooves and a plurality of second grooves. The plurality of first grooves extend along a first direction. The plurality of second grooves extend along a

### BRIEF DESCRIPTION OF THE DRAWINGS

FIG. 1 is a cross-sectional view illustrating an example of a configuration of a semiconductor manufacturing device according to an embodiment.

FIG. 2 is a perspective view illustrating an example of a configuration of a channel structure according to the embodiment.

FIG. 3 is a front view illustrating an example of the configuration of the channel structure according to the embodiment.

FIG. 4 is a cross-sectional view taken along line A-A in FIG. 3.

FIG. 5 is an enlarged front view illustrating an example of a configuration of a first surface of the channel structure according to the embodiment.

FIG. 6 is a cross-sectional view illustrating an example of a configuration of a groove according to the embodiment.

FIG. 7 is a cross-sectional view illustrating an example of the configuration of the groove according to the embodiment.

FIG. 8 is an enlarged front view illustrating another example of the configuration of the first surface of the channel structure according to the embodiment.

FIG. 9 is a cross-sectional view illustrating an example of a configuration of a channel structure according to another embodiment 1.

FIG. 10 is a front view illustrating an example of a configuration of a channel structure according to another embodiment 2.

FIG. 11 is a cross-sectional view taken along line B-B of FIG. 10.

FIG. 12 is a flowchart illustrating an example of a manufacturing process of the channel structure according to the embodiment.

FIG. 13 is a flowchart illustrating another example of the manufacturing process of the channel structure according to the embodiment.

### DESCRIPTION OF EMBODIMENTS

Hereinafter, embodiments of a channel structure, a semiconductor manufacturing device, and a method for manufacturing a channel structure disclosed in the present application will be described with reference to the accompanying drawings. Note that the present disclosure is not limited to the embodiments described below.

In the embodiments described below, expressions such as “constant”, “orthogonal”, “perpendicular”, and “parallel” may be used, but these expressions do not mean exactly “constant”, “orthogonal”, “perpendicular”, and “parallel”. In other words, it is assumed that the above expressions allow for deviations in manufacturing accuracy, installation accuracy, or the like.

In a semiconductor manufacturing process, a plasma processing device accommodates a wafer, which is an object to be processed, in a chamber and processes the wafer with plasma in a vacuum atmosphere. In the related art, there is disclosed a technique for reducing contamination of an object to be processed which is caused when a process by-product such as dust deposited on an inner wall of a chamber or the like is peeled off and falls on the object to be processed.

However, in the above-described related art, there is room for further improvement in reducing the contamination of the object to be processed. Therefore, there is a need for a technology capable of overcoming the above-described problems and reducing the contamination of the object to be processed due to process by-products.

### Semiconductor Manufacturing Device

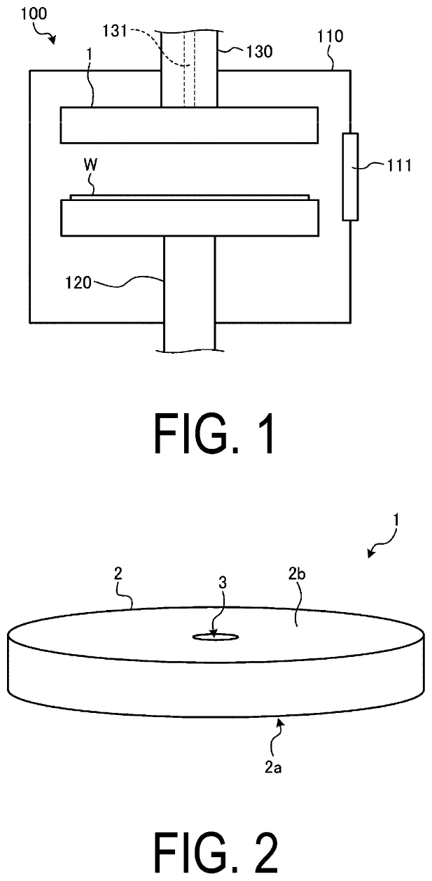

First, a configuration of a semiconductor manufacturing device 100 according to an embodiment will be described with reference to FIG. 1. FIG. 1 is a cross-sectional view illustrating an example of a configuration of a semiconductor manufacturing device 100 according to an embodiment.

The semiconductor manufacturing device 100 according to the embodiment is, for example, a plasma processing device that processes a semiconductor wafer W using plasma. Examples of the semiconductor manufacturing device 100 include a chemical vapor deposition (CVD) device and a dry etching device.

The semiconductor manufacturing device 100 according to the embodiment may include a channel structure 1, a chamber 110, a mounting table 120, and a shaft 130. The chamber 110 accommodates the channel structure 1, at least part of the mounting table 120, and at least part of the shaft 130.

The inside of the chamber 110 can be exhausted or depressurized by an exhauster (not illustrated) or the like. An opening 111 for loading and unloading the semiconductor wafer W may be located at a side portion of the chamber 110.

In the example illustrated in FIG. 1, the mounting table 120 is located below the channel structure 1 in the chamber 110. The mounting table 120 supports the semiconductor wafer W on a surface facing the channel structure 1, that is, on an upper surface of the mounting table 120.

The shaft 130 supports the channel structure 1 in the chamber 110 and introduces a medium such as a process gas into the channel structure 1. A through hole 131 is formed inside the shaft 130, and the through hole 131 is connected to a second opening 3 (see FIG. 2) of the channel structure 1. The mounting table 120 and the shaft 130 may be constituted by a ceramic. For example, aluminum oxide or aluminum nitride may be used as the ceramic.

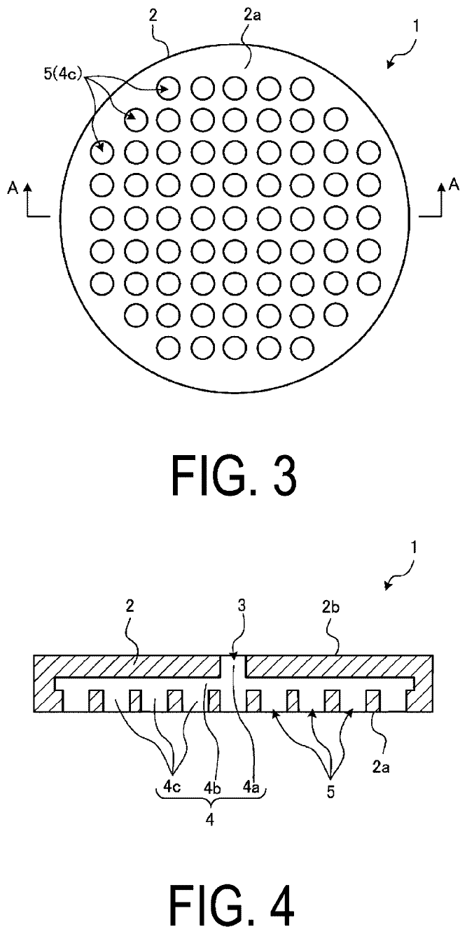

In the semiconductor manufacturing device 100, the process gas used for the plasma processing passes through the through hole 131 of the shaft 130 and a channel 4 (see FIG. 4) of the channel structure 1, and is led to the inside of the chamber 110 through a plurality of first openings 5 (see FIG. 3). That is, the channel structure 1 according to the embodiment may function as, for example, a shower plate in the semiconductor manufacturing device 100.

### Channel Structure

Next, the configuration of the channel structure 1 according to the embodiment will be described with reference to FIGS. 2 to 11. FIG. 2 is a perspective view illustrating an example of the configuration of the channel structure 1 according to the embodiment, and FIG. 3 is a front view illustrating an example of the configuration of the channel structure 1 according to the embodiment. FIG. 4 is a cross-sectional view taken along line A-A in FIG. 3.

As illustrated in FIGS. 2 to 4, the channel structure 1 according to the embodiment includes a base 2, and the channel 4 and the first openings 5 which are formed in the base 2. The base 2 may have a second opening 3 connected to the first openings 5 and the channel 4.

As illustrated in FIG. 2, the base 2 is, for example, disc-shaped and has a first surface 2a and a second surface 2b. In FIG. 2, the lower surface is the first surface 2a, and the upper surface is the second surface 2b. In the present disclosure, an example is described in which the base 2 is disc-shaped, but the shape of the base 2 is not limited to the disc shape, and may take any shape.

As illustrated in FIG. 4, the second opening 3 is located on the second surface 2b of the base 2, and the plurality of first openings 5 are located on the first surface 2a of the base 2. The second opening 3 and the plurality of first openings 5 are connected to each other by the channel 4.

For example, as illustrated in FIG. 2, the second opening 3 is located in a central portion of the second surface 2b of the base 2. As illustrated in FIG. 3, the plurality of first openings 5 may be located to be evenly distributed over the entire first surface 2a of the base 2.

In the present disclosure, an example is described in which one second opening 3 serving as an inflow opening of a medium such as a process gas is provided and the plurality of first openings 5 serving as discharge openings of the medium are provided, but the present disclosure is not limited thereto. For example, a plurality of the second openings 3 may be provided, or one first opening 5 may be provided.

As illustrated in FIG. 4, the channel 4 may include, in order from the side connected to the second opening 3, an introduction channel 4a, an extended width path 4b, and a plurality of branch paths 4c. The introduction channel 4a is, for example, a portion extending perpendicularly to the second surface 2b from the second opening 3.

The extended width path 4b is, for example, a portion extending in parallel to the first surface 2a from an end portion of the introduction channel 4a on the first surface 2a side. The plurality of branch paths 4c are sites respectively extending from the extended width path 4b to the plurality of first openings 5, for example. The configuration of the channel 4 of the present disclosure is not limited to the example of FIG. 4.

FIG. 5 is an enlarged front view illustrating an example of the configuration of the first surface 2a of the channel structure 1 according to the embodiment. As illustrated in FIG. 5, in addition to the plurality of first openings 5, a plurality of grooves 6 may be located on the first surface 2a of the base 2 according to the embodiment. The grooves 6 in the embodiment are not a processing flaw formed by processing such as grinding or polishing for flattening the first surface 2a.

In the embodiment, the maximum depth of the grooves 6 may be in a range from 5μm to 200 μm. With such a configuration, the falling of the process by-products can be reduced over a long period of time. In the embodiment, a surface roughness Ra of the portion of the first surface 2a other than the grooves 6 may be in a range from 0.1 μm to 5 μm. With such a configuration, dropping of process by-products due to impact, vibration, or the like can be reduced.

In the embodiment, as illustrated in FIG. 5, at least some of the plurality of grooves 6 may be connected to the first opening 5. Thus, the dropping of the process by-products even around the first opening 5 can be reduced.

When the surface area of the first surface 2a is increased only by roughening the first surface 2a by grinding or polishing, a large number of sharply pointed portions are formed on the first surface 2a. In such a case, the sharply pointed portion of the first surface 2a of the base 2 may be dropped by the corrosive reaction gas.

On the other hand, in the embodiment, since the plurality of grooves 6 larger than the polishing scratches are provided, the surface area of the first surface 2a is large.

That is, in the embodiment, since the surface area is increased by the grooves 6, the peeling of the process by-product deposited on the first surface 2a can be reduced. and the reliability of the channel structure 1 can be improved.

In the embodiment, as illustrated in FIG. 5, the plurality of grooves 6 may include a plurality of first grooves 6a and a plurality of second grooves 6b. The first grooves 6a are grooves extending along a first direction D1. The second grooves 6b are grooves extending along a second direction D2 intersecting the first direction D1. The second direction D2 may be, for example, a direction orthogonal to the first direction D1.

Here, in the embodiment, the first grooves 6a and the second grooves 6b extending along two different directions are located on the first surface 2a, the surface area of the first surface 2a is larger than that in the case where the grooves 6 are not provided, and the adhesion between the first surface 2a and the process by-product is high.

In the embodiment, since the first grooves 6a and the second grooves 6b extending along two different directions are located on the first surface 2a, the base 2 and the process by-products deposited on the first surface 2a are less likely to shrink and expand anisotropically during the temperature cycle in the process, as compared with a case where grooves extending only in one direction are provided.

Thus, the peeling of the process by-product deposited on the first surface 2a due to the shrinkage and expansion of the base 2 caused by the temperature cycle can be reduced.

That is, according to the embodiment, since the first grooves 6a and the second grooves 6b extending along two different directions are located on the first surface 2a, the contamination of the object to be processed by the process by-products can be reduced.

A method for manufacturing the channel structure 1 according to the embodiment is, for example, as follows. First, a tape containing a ceramic as a raw material and a binder is prepared. At this time, the first grooves 6a and the second grooves 6b are processed in a portion corresponding to the first surface 2a by using a mold in which convex portions corresponding to the first grooves 6a and the second grooves 6b are formed.

Subsequently, the tape is layered after being dried, and degreasing and firing are performed under conditions corresponding to the material of the tape, whereby the channel structure I can be obtained. By using such a tape layering method, the first grooves 6a and the second grooves 6b can be formed in the first surface 2a.

In the embodiment, each of the grooves 6 may have a substantially elliptical shape when the first surface 2a is viewed from the front.

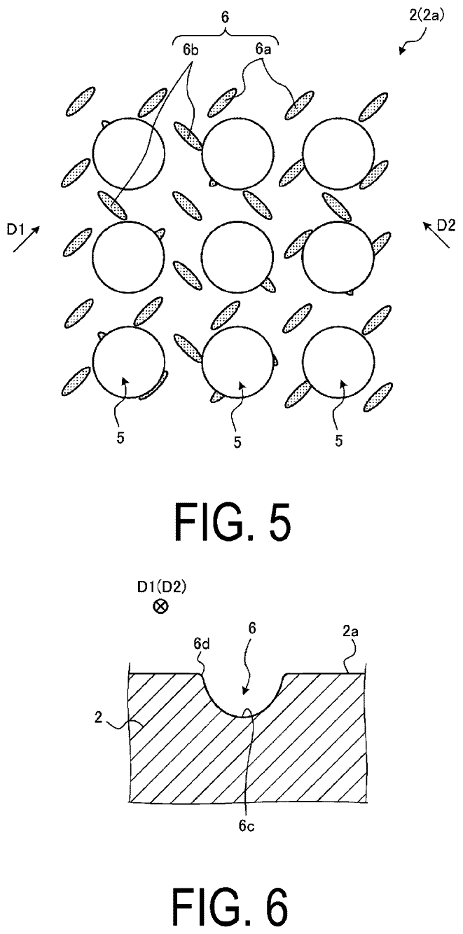

FIG. 6 is a cross-sectional view illustrating an example of the configuration of the groove 6 according to the embodiment, and is a cross-sectional view when viewed in a cross section orthogonal to the longitudinal direction of the groove 6, that is, a cross section orthogonal to the first direction DI of the first groove 6a (see FIG. 5) or the second direction D2 of the second groove 6b (see FIG. 5).

As illustrated in FIG. 6, in the embodiment, a bottom portion 6c of the groove 6 may be a curved line in a cross-sectional view orthogonal to the longitudinal direction of the groove 6. In this manner, by forming the bottom portion 6c of the groove 6 into a curved shape in a cross-sectional view orthogonal to the longitudinal direction, the surfaces can be smoothed when viewed microscopically, while the surface areas can be increased when viewed macroscopically.

Therefore, according to the embodiment, the peeling of the process by-product deposited on the first surface 2a can be reduced, and the reliability of the channel structure 1 can be improved.

In the embodiment, as illustrated in FIG. 6, an edge 6d of the groove 6 may have an R shape in a cross-sectional view orthogonal to the longitudinal direction of the groove 6. As a result, an unintended reaction of the edge 6d of the groove 6 with the corrosive reaction gas can be reduced, and thus the reliability of the channel structure 1 can be improved.

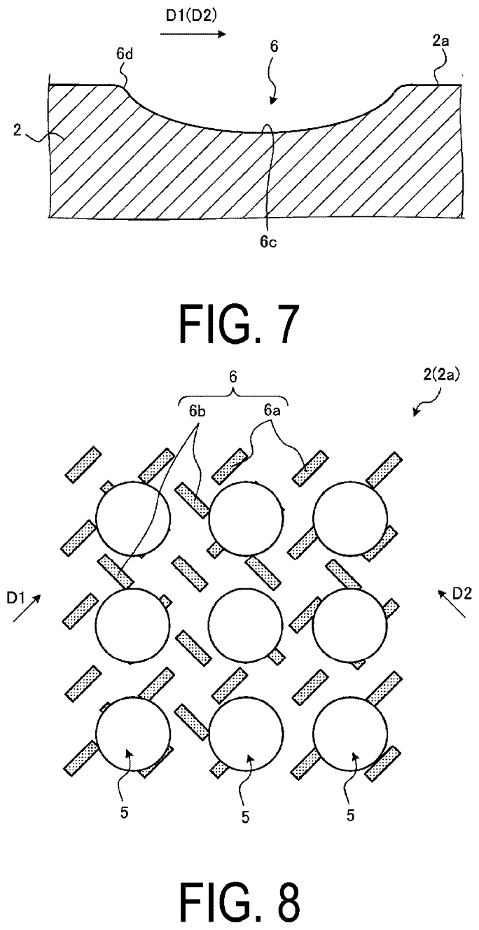

FIG. 7 is a cross-sectional view illustrating an example of the configuration of the groove 6 according to the embodiment, and is a cross-sectional view when viewed in a cross section along the longitudinal direction of the groove 6, that is, a cross section along the first direction DI of the first groove 6a (see FIG. 5) or the second direction D2 of the second groove 6b (see FIG. 5).

As illustrated in FIG. 7, in the embodiment, the bottom portion 6c of the groove 6 may be a curved line in a cross-sectional view along the longitudinal direction of the groove 6. In this manner, by forming the bottom portion 6c of the groove 6 into a curved shape in a cross-sectional view along the longitudinal direction, the surfaces can be made smooth when viewed microscopically, while the surface areas can be increased when viewed macroscopically.

Therefore, according to the embodiment, the peeling of the process by-product deposited on the first surface 2a can be reduced, and the reliability of the channel structure 1 can be improved.

In the embodiment, as illustrated in FIG. 7, the edge 6d of the groove 6 may have an R shape in a cross-sectional view along the longitudinal direction of the groove 6. As a result, unintended reaction of the edge 6d of the groove 6 with the corrosive reaction gas can be reduced, and thus the reliability of the channel structure 1 can be improved.

In the examples in FIGS. 5 to 7, an example in which the groove 6 has a substantially elliptical shape in a plan view is illustrated, but the present disclosure is not limited to such an example, and for example, as illustrated in FIG. 8, the groove 6 may have a substantially rectangular shape in a plan view. FIG. 8 is an enlarged front view illustrating another example of the configuration of the first surface 2a of the channel structure 1 according to the embodiment.

The groove 6 according to the embodiment is not limited to the substantially elliptical shape or the substantially rectangular shape, and may have any shape as long as the shape extends in the first direction DI and the second direction D2. The grooves 6 according to the embodiment are not limited to the two types of grooves 6 extending in two directions, and may be configured by three or more types of grooves extending along three or more directions.

The base 2 according to the embodiment may be constituted by any material such as a resin, a metal, or a ceramic. Meanwhile, when the base 2 is constituted by a ceramic, the base 2 is superior in mechanical strength, heat resistance, corrosion resistance, and the like compared with a case where the base 2 is constituted by a resin or a metal.

Here, ceramic refers to aluminum oxide ceramic, zirconium oxide ceramic, yttrium oxide ceramic, magnesium oxide ceramic, silicon nitride ceramic, aluminum nitride ceramic, silicon carbide ceramic, cordierite ceramic, mullite ceramic, or the like.

For example, aluminum oxide ceramic is a material in which aluminum oxide accounts for 70 mass % or more among 100 mass % of all the components which constitute the ceramic. Note that the same applies to other ceramics.

The material of a target base can be confirmed by the following method. First, a value of 2θ, which is a diffraction angle obtained by measurement of the target base using an X-ray diffractometer (XRD), is identified via a JCPDS card. Herein, a case where the presence of aluminum oxide is confirmed in the target base by XRD is described as an example.

Next, a quantitative analysis of aluminum (Al) is performed using an ICP emission spectrophotometer (ICP) or an X-ray fluorescent analyzer (XRF). When a content conversion-calculated from the content of Al measured by ICP or XRF to aluminum oxide (Al₂O₃) is 70 mass % or greater, the target base is constituted by aluminum oxide ceramic.

When the channel structure 1 of the present disclosure includes the plurality of first openings 5, and the base 2 is constituted by a ceramic, the channel structure 1 can be suitably used for a shower plate for use in the semiconductor manufacturing device 100 (see FIG. 1) required to have corrosion resistance. The channel structure 1 according to the embodiment reduces the deterioration in quality of the inflow gas, and accordingly, the object to be processed is of high quality.

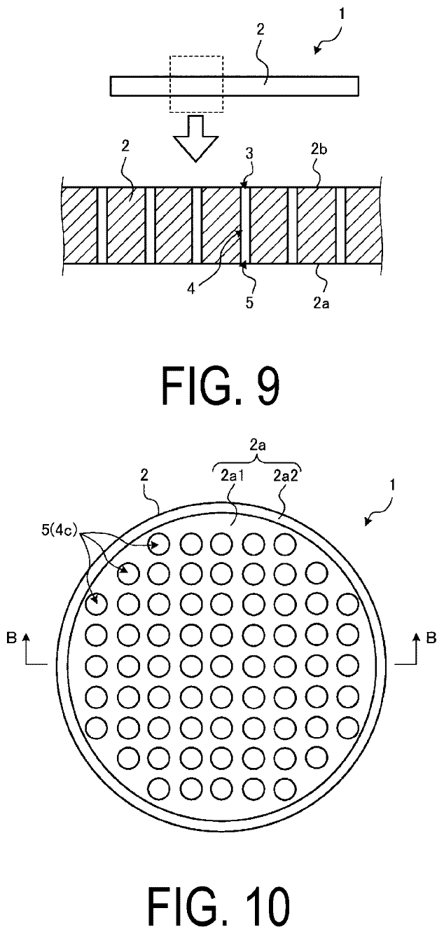

FIG. 9 is a cross-sectional view illustrating an example of a configuration of a channel structure 1 according to another embodiment 1. As illustrated in FIG. 9, in the channel structure 1 of another embodiment 1, an individual second opening 3 and channel 4 may be located for each first opening 5. Also in this case, as in the example of FIGS. 3 and 4 described above, a medium such as a process gas is caused to flow into the plurality of second openings 3, whereby the medium can be discharged from the plurality of first openings 5.

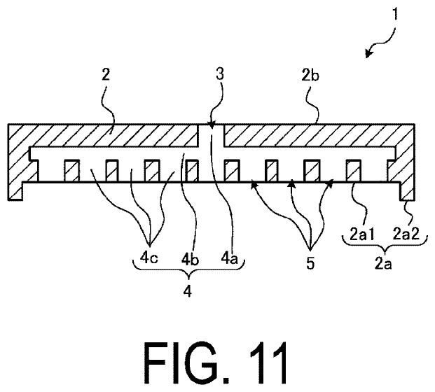

FIG. 10 is a front view illustrating an example of a configuration of a channel structure 1 according to another embodiment 2, and FIG. 11 is a cross-sectional view taken along line B-B illustrated in FIG. 10.

As illustrated in FIG. 10, in a channel structure 1 of another embodiment 2, a first surface 2a of the base 2 may include a first region 2a1 and a second region 2a2. The first region 2a1 is a substantially circular region in which the plurality of first openings 5 and the plurality of grooves 6 (see FIG. 5) are located. The second region 2a2 is an annular region surrounding the first region 2a1.

In another embodiment 2, as illustrated in FIG. 11, the height of the second region 2a2 may be different from the height of the first region 2a1. In other words, the second region 2a2 and the first region 2a1 may not be flush with each other. Thus, an annular sealing member, for example, a seal ring can be brought into good contact with the periphery of the first surface 2a.

In another embodiment 2, the surface roughness Ra of the second region 2a2 may be smaller than the surface roughness Ra of the first region 2a1. Accordingly, when the annular sealing member is brought into contact with the second region 2a2, the sealing member and the second region 2a2 can be brought into contact with each other without a clearance.

In the example in FIG. 11, an example in which the second region 2a2 protrudes with respect to the first region 2a1 is illustrated, but the present disclosure is not limited to such an example, and the second region 2a2 may be recessed with respect to the first region 2a1.

In the embodiment, the first surface 2a of the base 2 may have irregularities (not illustrated) formed by irradiation with a laser beam at the time of manufacturing. The first surface 2a having such irregularities may have a surface roughness Ra in a range from 0.5 μm to 10 μm, for example.

As a result, an anchor effect can be produced between the first surface 2a and the process by-products, so that the adhesion between the first surface 2a and the process by-products can be improved. Therefore, according to the embodiment, since the peeling of the process by-product can be suppressed, the contamination of the object to be processed by the process by-product can be suppressed.

### Manufacturing Process

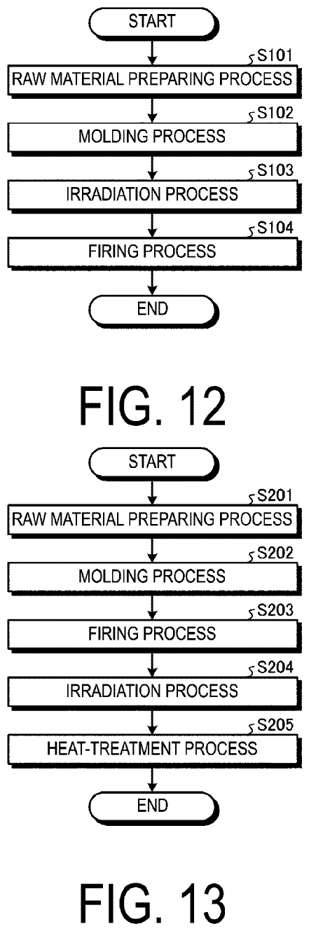

Next, a manufacturing process of the channel structure 1 according to the embodiment will be described in detail with reference to FIGS. 12 and 13. FIG. 12 is a flowchart illustrating an example of a manufacturing process of the channel structure 1 according to the embodiment.

As illustrated in FIG. 12, in the manufacturing process of the channel structure 1 according to the embodiment, first, a raw material preparing process is performed (step S101). In this process, for example, a ceramic raw material having a purity of 90% or more and an average particle diameter of about 1 μm is prepared, and a slurry obtained by adding and mixing predetermined amounts of a sintering aid, a binder, a solvent, a dispersant, and the like to the ceramic raw material is spray-dried and granulated by a spray granulation method (spray drying method) to obtain a primary raw material. Thus, the raw material preparing process is completed.

In the manufacturing process of the channel structure I according to the embodiment, next, a molding process is performed (step S102). In this process, for example, the primary raw material granulated by spray drying is charged into a rubber mold having a predetermined shape, and is molded into a disc shape by an isostatic press molding method (rubber press method). Thereafter, the disc-shaped molded body is removed from the rubber mold, and is subjected to machining processing.

In this machining processing, for example, a hole corresponding to the introduction channel 4a of the base 2 is formed in a disc-shaped molded body, and holes corresponding to the extended width path 4b and the plurality of branch paths 4c of the base 2 are formed in another disc-shaped molded body.

Next, the disc-shaped molded body including the introduction channel 4a and the disc-shaped molded body including the extended width path 4b and the plurality of branch paths 4c, which are formed by machining processing, are bonded to each other. As a result, a molded body having the introduction channel 4a, the extended width path 4b, and the plurality of branch paths 4c is obtained, and the molding process is finished.

For this bonding, for example, a bonding agent made of a slurry produced by weighing and mixing predetermined amounts of the ceramic raw material, the sintering aid, the binder, the dispersant, and the solvent used for producing the molded body is used. In this molding process, a plurality of grooves 6 may be formed in the first surface 2a by using a conventionally known method.

In the manufacturing process of the channel structure 1 according to the embodiment, next, an irradiation process is performed (step S103). In this process, for example, a laser beam having peak wavelengths in a range from 150 nm to 11000 nm and spot diameters in a range from 5 μm to 200 μm is applied to a necessary portion of the first surface 2a of the molded body in an atmosphere corresponding to the ceramic raw material of the molded body. Thus, irregularities are formed on the first surface 2a.

In the manufacturing process of the channel structure 1 according to the embodiment, next, a firing process is performed (step S104). In this process, for example, the molded body is fired at a temperature corresponding to the ceramic raw material of the molded body in an atmosphere corresponding to the ceramic raw material of the molded body. Thus, the channel structure 1 according to the embodiment is obtained.

In the example of FIG. 12 described above, irradiation with the laser beam is performed before the molded body made of the ceramic material is fired, and thus desired irregularities on the first surface 2a even with a relatively low laser power can be formed That is, in the example in FIG. 5, the channel structure 1 can be easily manufactured.

FIG. 13 is a flowchart illustrating another example of the manufacturing process of the channel structure 1 according to the embodiment. As illustrated in FIG. 13, in the manufacturing process of the channel structure 1 according to another example, first, a raw material preparing process is performed (step S201), and then a molding process is performed (step S202).

The processes of the step S201 and the step S202 are the same as the processes of the step S101 and the step S102 described above, and thus detailed description thereof is omitted.

In the manufacturing process of the channel structure 1 according to another example, next, a firing process is performed (step S203). In this process, for example, the molded body is fired at a temperature corresponding to the ceramic raw material of the molded body in an atmosphere corresponding to the ceramic raw material of the molded body.

In the manufacturing process of the channel structure 1 according to another example, next, an irradiation process is performed (step S204). In this process, for example, a necessary portion of the first surface 2a of the sintered body is irradiated with a laser beam having peak wavelengths in a range from 150 nm to 11000 nm and spot diameters in a range from 5 μm to 200 μm in an atmosphere corresponding to the sintered body. Thus, irregularities are formed on the first surface 2a.

In the example in FIG. 6, desired irregularities on the first surface 2a can be accurately formed by irradiating the sintered body with the laser beam after being fired.

In the manufacturing process of the channel structure 1 according to another example, next, a heat-treatment process is performed (step S205). In this process, for example, the sintered body irradiated with the laser beam is heat-treated in a temperature range from 500° C. to 1600° C. in an atmosphere corresponding to the sintered body.

Thus, in the process of step S204 described above, the color of the portion discolored by the irradiation with the laser beam can be returned to the original color. Therefore, according to another example, when the first surface 2a of the channel structure 1 is discolored due to a corrosive atmosphere or the like during a process, such discoloration can be easily visually recognized.

The channel structure 1 according to the embodiment includes the base 2 and the channel 4. The base 2 has the first opening 5 on the first surface 2a. The channel 4 is located inside the base 2 and is connected to the first opening 5. The base 2 has a plurality of grooves 6 on the first surface 2a. The plurality of grooves 6 include the plurality of first grooves 6a and the plurality of second grooves 6b. The plurality of first grooves 6a extend along the first direction D1. The plurality of second grooves 6b extend along the second direction D2 intersecting the first direction D1. Thus, contamination of the object to be processed due to process by-products can be reduced.

The method for manufacturing the channel structure 1 according to the embodiment includes the preparing process (step S102), the irradiating process (step S103), and the firing process (step S104). In the preparing process (step S102), a molded body is prepared which includes the base 2 made of a ceramic raw material and having the plurality of first openings 5 on the first surface 2a, and the channel 4 located inside the base 2 and connected to the plurality of first openings 5. In the irradiation process (step S103), the first surface 2a of the molded body is irradiated with the laser beam. In the firing process (step S104), the molded body irradiated with the laser beam is fired. Thus, contamination of the object to be processed due to process by-products can be reduced.

The method for manufacturing the channel structure 1 according to the embodiment includes the preparing process (step S202), the firing process (step S203), and the irradiating process (step S204). In the preparing process (step S202), a molded body is prepared which includes the base 2 made of a ceramic raw material and having the plurality of first openings 5 on the first surface 2a, and the channel 4 located inside the base 2 and connected to the plurality of first openings 5. In the firing process (step S203), the molded body is fired to form a sintered body. In the irradiation process (step S204), the first surface 2a of the sintered body is irradiated with the laser beam. Thus, contamination of the object to be processed due to process by-products can be reduced.

The method for manufacturing the channel structure 1 according to the embodiment further includes the heat-treatment process (step S205) of the sintered body irradiated with the laser beam in a temperature range from 500° C. to 1600° C. Thus, when the first surface 2a of the channel structure 1 is discolored due to a corrosive atmosphere or the like during a process, the discoloration can be easily visually recognized.

Although an embodiment of the present disclosure has been described above, the present disclosure is not limited to the embodiment described above, and various changes can be made without departing from the spirit of the present disclosure.

Additional effects and other aspects can be easily derived by a person skilled in the art. Thus, a wide variety of aspects of the present disclosure are not limited to the specific details and representative embodiments represented and described above. Accordingly, various changes are possible without departing from the spirit or scope of the general inventive concepts defined by the appended claims and their equivalents.

### REFERENCE SIGNS

1 Channel structure
2 Base
2a First surface
4 Channel
5 First opening
6 Groove
6a First groove
6b Second groove
6c Bottom portion
6d Edge
100 Semiconductor manufacturing device
110 Chamber
120 Mounting table
D1 First direction
D2 Second direction

1. A channel structure comprising:
a base comprising a first opening on a first surface; and
a channel located inside the base and connected to the first opening, wherein
the base comprises a plurality of grooves on the first surface, and
the plurality of grooves comprise:
a plurality of first grooves extending along a first direction; and
a plurality of second grooves extending along a second direction intersecting with the first direction.

2. The channel structure according to claim 1, wherein
the groove has a substantially elliptical shape when the first surface is viewed from the front.

3. The channel structure according to claim 1, wherein
a bottom portion of the groove is curved in a cross-sectional view orthogonal to a longitudinal direction of the groove.

4. The channel structure according to claim 1, wherein
a bottom portion of the groove is curved in a cross-sectional view along a longitudinal direction of the groove.

5. The channel structure according to claim 1, wherein
a maximum depth of the groove is in a range from 5 μm to 200 μm.

6. The channel structure according to claim 1, wherein
a surface roughness Ra of a portion of the first surface other than the groove is in a range from 0.1 μm to 5 μm.

7. The channel structure according to claim 1, wherein
the first surface comprises:
a first region in which a plurality of the first openings and the plurality of grooves are located; and
a second region surrounding the first region and having a height different from a height of the first region.

8. The channel structure according to claim 7, wherein
a surface roughness Ra of the second region is smaller than a surface roughness Ra of the first region.

9. The channel structure according to claim 1, wherein
at least some of the plurality of grooves are connected to the first opening.

10. A semiconductor manufacturing device comprising:
a mounting table;
a chamber; and
the channel structure according to claim 1.

11. A method for manufacturing a channel structure, comprising:
preparing a molded body comprising a base and a channel, the base being made of a ceramic raw material and comprising a plurality of first openings on a first surface, the channel being located inside the base and connected to the plurality of first openings;
irradiating the first surface of the molded body with a laser beam; and
firing the molded body irradiated with the laser beam.

12. A method for manufacturing a channel structure, comprising:
preparing a molded body comprising a base and a channel, the base being made of a ceramic raw material and comprising a plurality of first openings on a first surface, the channel being located inside the base and connected to the plurality of first openings;
firing the molded body to form a sintered body; and
irradiating the first surface of the sintered body with a laser beam.

13. The method of manufacturing a channel structure according to claim 12, further comprising:
heat-treating the sintered body irradiated with the laser beam in a temperature range from 500° C. to 1600° C.
